(19) United States
(12) Patent Application Publication
(10) Pub. No.: US 2007/0181967 A1
(43) Pub. Date: Aug. 9, 2007

(54) Semiconductor device with visible indicator and method of fabricating the same

(76) Inventors: Ja-Young Choi, Seongnam-si (KR); Hyung-Woo Kim, Suwon-si (KR)

Correspondence Address: HARNESS, DICKEY & PIERCE, P.L.C., P.O. BOX 8910, RESTON, VA, 20195, US

(21) Appl. No.: 11/635,628

(22) Filed: Dec. 8, 2006

(30) Foreign Application Priority Data
Dec. 8, 2005 (KR) 10-2005-0119515

(51) Int. Cl. H01L 29/00

(52) U.S. Cl. 257/529

(57) ABSTRACT

A semiconductor device may include a fuse pattern and an interconnection pattern formed on a surface of a semiconductor substrate. An interlayer dielectric layer may be disposed on the surface of the semiconductor substrate including the fuse pattern and the interconnection pattern. A bonding pad may be formed over the interconnection pattern and connected to the interconnection pattern through the interlayer dielectric layer. A visible indicator may be formed in the interlayer dielectric layer near the bonding pad. The visible indicator may indicate a bonding region and a probing region of the bonding pad.

### PRIORITY STATEMENT

This U.S non-provisional patent application claims the benefit of priority under 35 U.S.C § 119 of Korean Patent Application 2005-119515, filed on Dec. 8, 2005 in the Korean Intellectual Property Office (KIPO), the entirety of which is hereby incorporated by reference.

### BACKGROUND

1. Field

Example embodiments relate to semiconductor device and method of fabricating the same. For example, a semiconductor device with a visible indicator and a method of fabricating the same.

2. Description of Related Art

A semiconductor device may include a bonding pad configured to input and/or output a power or external signal. Bonding bumper or wire may be bonded to the bonding pad to maintain reliability of the semiconductor device.

After a fabricating process is completed, a semiconductor device may be tested. During the test of the semiconductor device, a portion of a bonding pad may be selectively probed. A surface defect may occur on a probe-contact portion of the bonding pad when a metal layer is partially lifted and/or pushed. If a bonding pad is probed several times, for example, while a variety of tests are being performed, the bonding pad may be damaged and may result in poorer contact between the bumper or wire and the bonding pad.

Accordingly, attempts have been made to address such a problem. One of these attempts includes a bonding pad on a test line that may be divided into a voluntary bonding region and a probing region. A probe may contact only the probing region to secure a wire or bumper bonding region.

FIG. 1 is a top plan view of a conventional bonding pad 10 formed on a semiconductor device. A portion of the bonding pad 10 may have an oblong shape within a range that space permits, that may separate a bonding region from a probing region. An operator of a test line may test a semiconductor device by visibly assigning a portion of the bonding pad 10 to a bonding region “A” and a probing region “B”, and contacting a probe to the bonding region “A”. A contact portion of a probe 14 may make contact in overlap 16, which may corresponds to about 20 percent of the bonding region “A” that bumper or wire 12 may be in contact with. However, the selection of the bonding region “A” and the probing region “B” may vary with each individual operator. Therefore, a probe may be pushed deeper into the bonding region “A,” which may cause a poorer wire or bumper bonding in a subsequent process.

Conventional approaches have been suggested to overcome the foregoing problem. For example, steps may be formed on a bonding pad or an insulation layer may be provided on a bonding pad to separate a bonding region from a probing region. However, an insulation layer or a metal layer of the bonding pad may be lifted and bonded to the bonding region which may cause a poor bond.

### SUMMARY

According to an example embodiment, a semiconductor device may include a fuse pattern and an interconnection pattern formed on a surface of a semiconductor substrate; an interlayer dielectric layer disposed on the semiconductor substrate including the fuse pattern and the interconnection pattern, the interlayer dielectric layer including a fuse opening in the interlayer dielectric layer that exposes the fuse pattern; a bonding pad formed over the interconnection pattern and connected to the interconnection pattern through the interlayer dielectric layer; and a visible indicator formed in the interlayer dielectric layer near or in the vicinity of the bonding pad, the visible indicator indicating a bonding region and a probing region of the bonding pad.

According to an example embodiment, a method of fabricating a semiconductor device may include forming an interconnection pattern and a fuse pattern on a surface of a semiconductor substrate; forming an interlayer dielectric layer on the surface of the semiconductor substrate including the interconnection pattern and the fuse pattern; patterning the interlayer dielectric layer to expose a portion of the interconnection pattern; forming a bonding pad connected to the exposed interconnection pattern; forming a fuse opening by removing a portion of the interlayer dielectric layer on the fuse pattern; and forming a visible indicator by removing a portion of the interlayer dielectric layer in the vicinity of the bonding pad.

### BRIEF DESCRIPTION OF THE DRAWINGS

Example embodiments will be described with reference to the accompanying drawings.

FIG. 1 illustrates a conventional bonding pad where a bonding region and a probing region are not separated from each other.

FIG. 2 is a top plan view of a semiconductor device according to an example embodiment.

FIG. 3 is a cross-sectional view taken along a line I-I′ of FIG. 2.

FIG. 4 is a top plan view of a semiconductor device according to an example embodiment.

FIG. 5 is a top plan view of a semiconductor device according to an example embodiment.

FIG. 6 and FIG. 7 are top plan views of semiconductor chips according to an example embodiment.

FIG. 8 through FIG. 10 are cross-sectional views of a method of fabricating a semiconductor device according to an example embodiment.

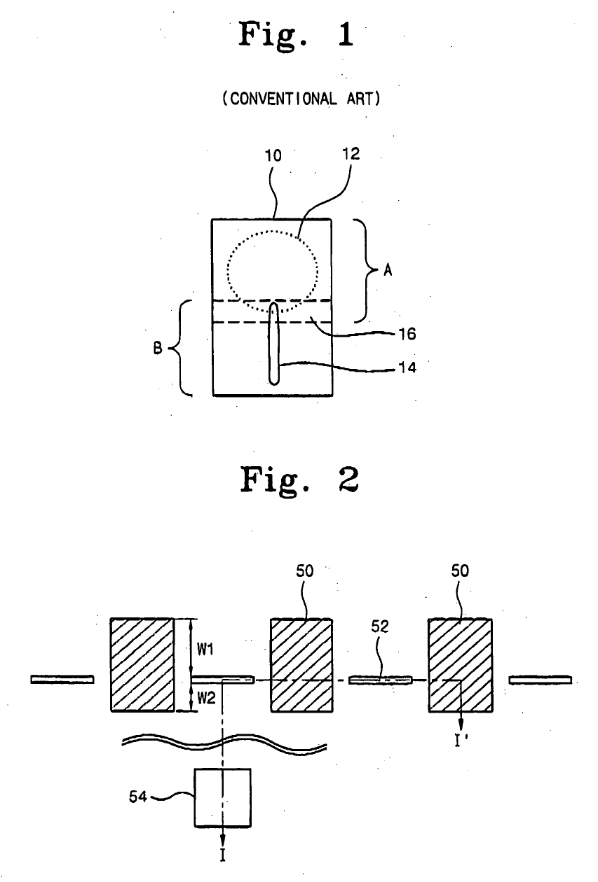

### DESCRIPTION OF EXAMPLE EMBODIMENTS

Example embodiments will now be described more fully hereinafter with reference to the accompanying drawings, in which example embodiments are shown. Example embodiments, however, may be embodied in many different forms and should not be construed as limited to the embodiments set forth herein. Rather, these example embodiments are provided so that this disclosure will be thorough, and will convey the scope to those skilled in the art.

It will be understood that when an element or layer is referred to as being “on”, “connected to” or “coupled to” another element or layer, it may be directly on, connected or coupled to the other element or layer or intervening elements or layers may be present. In contrast, when an element is referred to as being “directly on,” “directly connected to” or “directly coupled to” another element or layer, there may be no intervening elements or layers present. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting. As used herein, the singular forms “a”, “an” and “the” may be intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments may be described herein with reference to cross-section illustrations that may be schematic illustrations of idealized embodiments (and intermediate structures). The thicknesses of layers and regions are exaggerated for clarity. As such, variations from the shapes of the illustrations as a result, for example, of manufacturing techniques and/or tolerances, are to be expected. Thus, the example embodiments should not be construed as limited to the particular shapes of regions illustrated herein but are to include deviations in shapes that result, for example, from manufacturing. Thus, the regions illustrated in the drawings are schematic in nature and their shapes are not intended to illustrate the actual shape of a region of a device and are not intended to limit the example embodiments. Like numbers refer to like elements throughout.

Unless otherwise defined, all terms (including technical and scientific terms) used herein have the same meaning as commonly understood by one of ordinary skill in the art. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

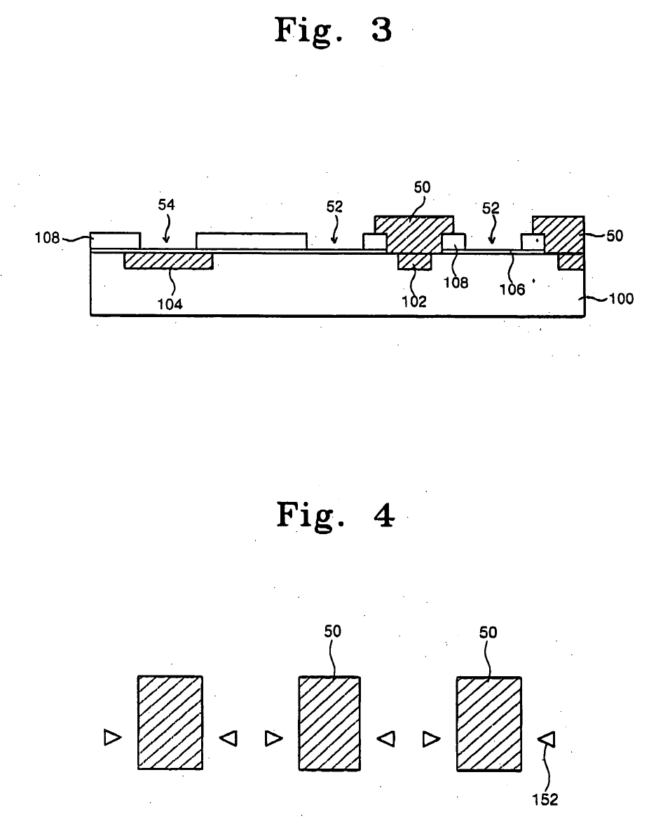

FIG. 2 is a top plan view of a semiconductor device with a visible indicator according to an example embodiment, and FIG. 3 is a cross-sectional view taken along a line I-I′ of FIG. 2.

Referring to FIG. 2 and FIG. 3, a plurality of bonding pads 50 may be disposed on a semiconductor substrate 100. A fuse opening 54 may be formed at a predetermined or desired region of the semiconductor substrate 100 to cut or attach a fuse pattern 104 for repairing a circuit. For example, the fuse opening 54 may be used to replace a defective cell with a redundancy cell. A fuse opening 54 may be formed in a memory device, and may also be formed in a hybrid semiconductor device in which a system LSI and a memory device may be merged.

An interconnection pattern 102 and a fuse pattern 104 may be disposed on the semiconductor substrate 100. An interlayer dielectric 108 may be disposed on the semiconductor substrate 100, including the interconnection pattern 102 and the fuse pattern 104. The fuse opening 54 may be formed by removing a portion of the interlayer dielectric 108 to expose the fuse pattern 104. A fuse encapsulation layer 106 having an etch selectivity with respect to the interlayer dielectric 108 may be interposed between the interlayer dielectric 108 and the semiconductor substrate 100. The fuse opening 54 may be formed by removing the interlayer dielectric 108 using the fuse encapsulation layer 106 as an etch-stop layer.

A bonding pad 50 may be disposed over the interconnection pattern 102 and may be connected to the interconnection pattern 102 through the interlayer dielectric 108. The bonding pad 50 also may be connected to the interconnection pattern 102 through the fuse encapsulation layer 106. A visible indicator 52 may be disposed on a substrate on one side or on opposite sides of the bonding pad 50 to divide the bonding pad 50 into a bonding region and a probing region. Similar to the fuse opening 54, the visible indicator 52 may be formed by removing the interlayer dielectric 108 and may be formed simultaneously with the fuse opening 54. For example, the visible indicator 52 may be formed by removing the interlayer dielectric 108 using the fuse encapsulation layer 106 as an etch stop layer simultaneously with the formation of the fuse opening 54. Therefore, the visible indicator 52 may have the same depth as the fuse opening 54. The visible indicator 52 may be spaced apart from the bonding pad 50.

As illustrated in FIG. 2, the visible indicator 52 may be formed in the shape of a bar with a major axis facing toward the bonding pad 50. For example, the visible indicator 52 may be disposed on a virtual line crossing over a predetermined or desired portion of the bonding pad 50 to identify (and/or separate) a bonding region from a probing region. A width W1 of the bonding region may be larger than a width W2 of the probing region. For example, an area of a probe-contact region in the bonding pad 50 may be reduced to maintain an original region to which a bumper or wire is bonded.

As illustrated in FIG. 4, the visible indicator 52 may be formed in the shape of triangle having a vertex directed toward the bonding pad 50. The visible indicator 52 may clearly identify (and/or separate) a bonding region from a probing region of the bonding pad 50. For example, other than a portion of the surface of the semiconductor substrate 100 where the visible indicator 52 is formed, the space between the bonding pads 50 may be utilized for another object. The visible indicator 52 may not be limited in shape and may be formed in a variety of shapes that may enable an operator to recognize the division between a fuse pattern region and a bonding region.

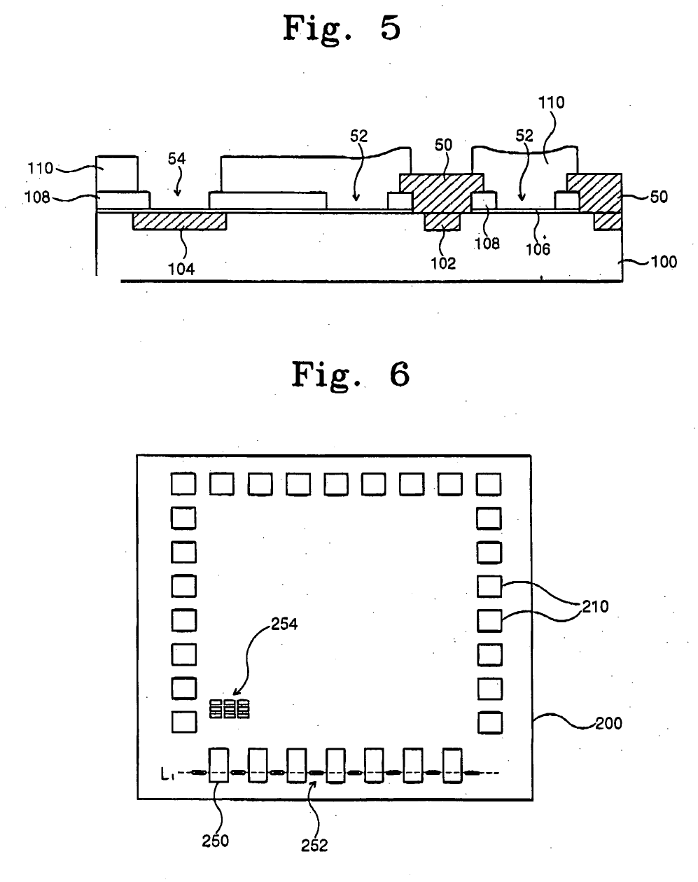

Referring to FIG. 5, the semiconductor device may include a protective layer 110 disposed to cover an entire surface of a substrate where the pad opening 54 and the visible indicator 52 may be formed. For example, the protective layer 110 may be made of a material that is transparent enough to recognize the visible indicator 52, e.g., an insulating material in the polymer group. The protective layer 110 may be used to protect a semiconductor device from the external environment in a semiconductor fabricating process. Openings may be formed in the protective layer 110 to expose the bonding pad 50 and/or the fuse opening 54.

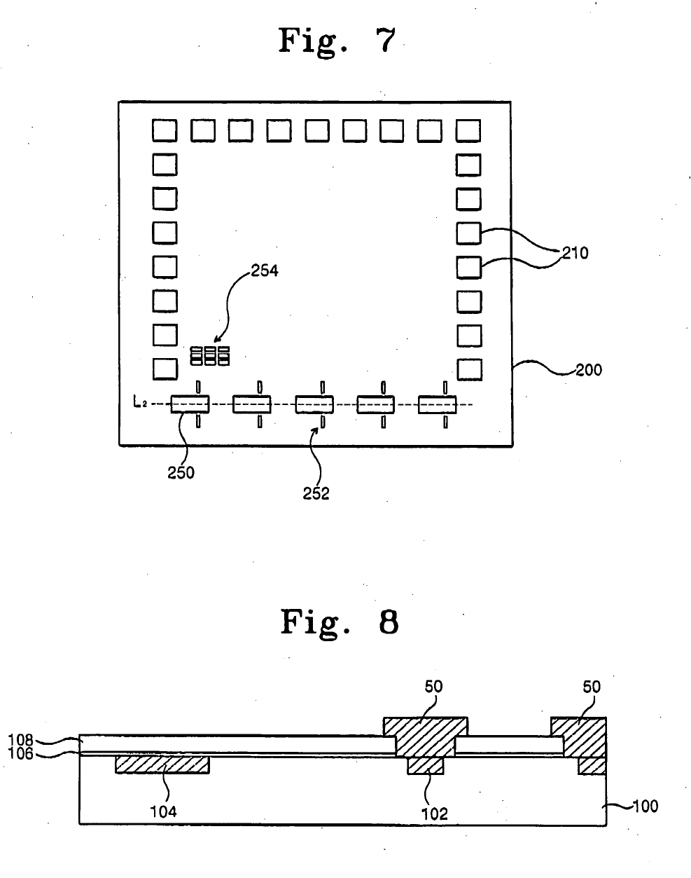

FIG. 6 and FIG. 7 are top plan views of semiconductor chips according to example embodiments.

Referring to FIG. 6, a plurality of bonding pads may be disposed on a semiconductor chip 200. The bonding pads may input and/or output a power or external signal. In designing the bonding pads 210 and 250, the disposition regions may vary depending on the kind of semiconductor devices used. When the bonding pads 210 and 250 are packaged, bumper or wire may not be bonded, and some pads may be probed during a test after a fabricating process is completed.

Generally, bonding pads may be formed to have a square structure 210. Bonding pads 250 that may be bonded frequently during a test may be formed to have a rectangular structure. Bonding pads 210 and 250 may be arranged in lines. A visible indicator 252 may be formed on one side or on opposite sides of a bonding pad 250 where probing may be conducted. The visible indicator 252 may be formed at a position on a virtual line L₁ that may be parallel to the direction of the line in which the bonding pads 250 are arranged. The major axis of the visible indicator 252 may be parallel to the virtual line L₁. Although the visible indicator 252 illustrated in the figures may be formed in the shape of a bar, it may be formed in various shapes. A plurality of fuse openings 254 may be formed on a predetermined or desired region of the semiconductor chip 200. The fuse openings 254 and the visible indicator 252 may be formed simultaneously so that they may have a substantially identical layer structure.

Referring to FIG. 7, rectangular-shaped bonding pads 250 may be arranged in a line. Unlike FIG. 6, in FIG. 7 the bonding pads 250 may be oriented so that the major axes of the bonding pads 250 are parallel to the direction of the line in which the bonding pads 250 are arranged. A visible indicator 252 may be formed so that the major axis of the visible indicator 252 is perpendicular to a virtual line L₂ that is parallel to the direction of the line in which the bonding pads 250 are arranged. The visible indicator 252 may be formed on one side or on opposite sides of the bonding pads 250.

While a visible indicator 252 formed near or in the vicinity of a rectangular-shaped bonding pad 250 that may be probed during a test has been described with reference to FIG. 6 and FIG. 7, a visible indicator 252 may also be formed near or in the vicinity of a rectangular-shaped bonding pad 250 to identify (and/or separate) a probing region from a bonding region.

A method of fabricating a semiconductor device according to an example embodiment will now be described with reference to FIG. 8 through FIG. 10.

Referring to FIG. 8, a unit device and an interconnection layer may be formed on a semiconductor substrate by means of conventional processes. A multilayered interconnection pattern 102 and a fuse pattern 104 may be formed on a predetermined or desired region of the substrate 100. For example, the fuse pattern 104 may be made of the same material as the interconnection pattern 102 or may be a part of a metal layer constituting the interconnection pattern 102. However, the fuse pattern 104 may be made as a part of another element constituting a semiconductor device.

An interlayer dielectric 108 may be formed on an entire surface of the substrate 100, including the interconnection pattern 102 and the fuse pattern 104. A fuse encapsulation layer 106 may be interposed between the interlayer dielectric layer 108 and the surface of the substrate 100 to cover the fuse pattern 104. The fuse encapsulation layer 106 may have an etch selectivity with respect to the interlayer dielectric 108.

The interlayer dielectric 108 and the fuse encapsulation layer 106 may be etched to expose a portion of the interconnection pattern 102 and to form a bonding pad 50. The bonding pad 50 may be connected to the interconnection pattern 102 through the interlayer dielectric 108.

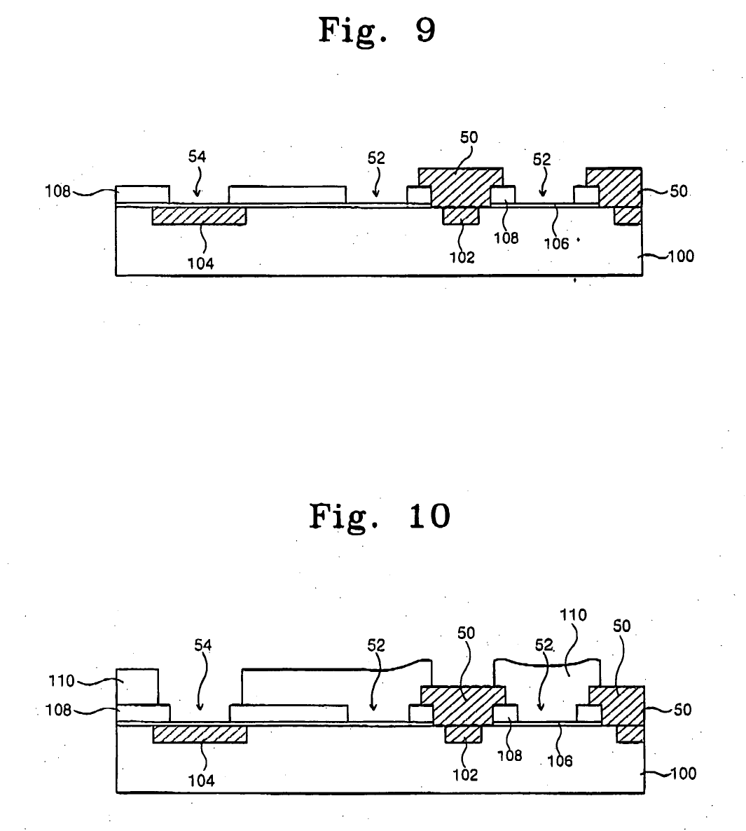

Referring to FIG. 9, the interlayer dielectric 108 may be etched to form a visible indicator 52 and a fuse opening 54. The visible indicator 52 and the fuse opening 54 may be formed simultaneously so as to have the same depth. The fuse encapsulation layer 106 may be used as an etch-stop layer during the etching of the interlayer dielectric layer 108 in order to etch the visible indicator 52 and the fuse opening 54. The fuse encapsulation layer 106 may be formed at a predetermined or desired thickness covering the fuse pattern 104 to prevent contamination resulting from fuse pattern cutting.

Referring to FIG. 10, a protective layer 110 may be formed on an entire surface of the substrate 100, including the visible indicator 52 and the fuse opening 54. The protective layer 110 may be etched, forming an opening to expose the fuse opening 54 and the bonding pad 50. For example, the protective layer 110 may be made of an organic material for use in conventional semiconductor fabricating processes.

As explained above, according to an example embodiment, a visible indicator may be formed at an interlayer dielectric near or in the vicinity of a bonding pad to divide the bonding pad into a bonding region and a probing region. A fuse opening may be formed simultaneously to the formation of the visible indicator to reduce process steps. The visible indicator may be spaced apart from the fuse opening, which may prevent material from the visible indicator from contaminating the bonding region during probing.

Although example embodiments have been described in connection with the accompanying drawings, example embodiments are not limited thereto. It will be apparent to those skilled in the art that various substitutions, modifications and changes may be made without departing from the scope and spirit of the example embodiments.

What is claimed is:

1. A semiconductor device comprising:
a fuse pattern and an interconnection pattern formed on a surface of a semiconductor substrate;
an interlayer dielectric layer disposed on the surface of the semiconductor substrate including the fuse pattern and the interconnection pattern, the interlayer dielectric layer having a fuse opening formed in the interlayer dielectric layer that exposes the fuse pattern;
a bonding pad formed over the interconnection pattern and connected to the interconnection pattern through the interlayer dielectric layer; and
a visible indicator in the interlayer dielectric layer near the bonding pad, the visible indicator indicating a bonding region and a probing region of the bonding pad.

2. The semiconductor device of claim 1, wherein the visible indicator is spaced apart from the bonding pad.

3. The semiconductor device of claim 1, wherein a plurality of bonding pads are arranged in a line.

4. The semiconductor device of claim 3, wherein the visible indicator is located along a line parallel to the direction of the line in which the bonding pads are arranged.

5. The semiconductor device of claim 3, wherein the visible indicator is located perpendicular to a line parallel to the direction of the line in which the bonding pads are arranged.

6. The semiconductor device of claim 1, wherein the bonding pad is in the shape of a rectangle.

7. The semiconductor device of claim 6, wherein:
the visible indicator is located along a line parallel with a minor axis of the bonding pad,
the line on which the visible indicator is located indicates where the bonding region and the probing region.

8. The semiconductor device of claim 6, wherein:
the visible indicator is located on a line running parallel to a major axis of the bonding pad,
the line on which the visible indicator is located indicates where the bonding region and the probing region.

9. The semiconductor device of claim 1, wherein the visible indicator is in the shape of a bar with a major axis facing toward the bonding pad.

10. The semiconductor device of claim 1, wherein the visible indicator is in the shape of triangle with a vertex directed toward the bonding pad.

11. The semiconductor device of claim 1, further comprising:
a protective layer on an entire surface of the semiconductor substrate and having an opening to expose the fuse pattern and the bonding pad.

12. The semiconductor device of claim 1, wherein the visible indicator is located on at least one side of the bonding pad.

13. The semiconductor device of claim 1, further comprising:
a fuse encapsulation layer interposed between the interlayer dielectric layer and the surface of the semiconductor substrate,
wherein the fuse opening and the visible indicator are formed by removing the interlayer dielectric layer using the fuse encapsulation layer as an etch-stop layer.

14. A method of fabricating a semiconductor device, comprising:
forming an interconnection pattern and a fuse pattern on a surface of a semiconductor substrate;
forming an interlayer dielectric layer on the surface of the semiconductor substrate including the interconnection pattern and the fuse pattern;
patterning the interlayer dielectric layer to expose a portion of the interconnection pattern;
forming a bonding pad connected to the exposed interconnection pattern;
forming a fuse opening by removing a portion of the interlayer dielectric layer on the fuse pattern; and
forming a visible indicator by removing a portion of the interlayer dielectric layer in the vicinity of the bonding pad.

15. The method of claim 14, wherein forming the fuse opening and forming the visible indicator are performed simultaneously.

16. The method of claim 14, wherein forming the visible indicator includes removing a portion of the interlayer dielectric layer spaced apart from the bonding pad.

17. The method of claim 14, wherein the visible indicator is located on at least one side of the bonding pad.

18. The method of claim 14, further comprising:
forming a fuse encapsulation layer interposed between the interlayer dielectric layer and a surface of the semiconductor substrate, the fuse encapsulation layer covering the fuse pattern and the interconnection pattern,
wherein forming the fuse opening and the visible indicator includes removing a portion of the interlayer dielectric layer by using the fuse encapsulation layer as an etch-stop layer.

19. The method of claim 14, further comprising:
forming a protective layer on the entire surface of the semiconductor substrate, the protective layer having an opening to expose the fuse pattern and the bonding pad.
